(19) United States
(12) Patent Application Publication
(10) Pub. No.: US 2015/0261018 A1
(43) Pub. Date: Sep. 17, 2015

(54) Thermochromic Optical Elements

(71) Applicant: Eric Colin Bretschneider, Bowling Green, KY (US)

(72) Inventor: Eric Colin Bretschneider, Bowling Green, KY (US)

(21) Appl. No.: 14/214,944

(22) Filed: Mar. 16, 2014

(51) Int. Cl. G02F 1/01; H01L 33/60; H01L 25/075; H01L 33/50

(52) U.S. Cl. CPC G02F 1/0147; H01L 33/507; H01L 33/60; H01L 25/0753

(57) ABSTRACT

A new method for chromaticity control in light fixtures in which the chromaticity of the light source in the fixture changes with temperature. Chromaticity variations in the light output of the fixture may be minimized by using thermochromic materials incorporated into various optical elements. As the temperature of the light source changes, the optical elements experience similar temperature changes. Changes in reflectance spectrum or transmission spectrum of the thermochromic optical elements modify the chromatic output of the light source in a manner to reduce the chromaticity of the light emitted by the fixture. This is a passive process that requires no additional control electronics or feedback. The method has particular advantages when used with so-called hybrid white light emitting diode products which include a nominally white light emitting diode and a red light emitting diode.

### RELATED APPLICATION

This application claims the benefit of priority from U.S. Application No. 61/793,795 filed on Mar. 15, 2013, the contents of which are hereby incorporated by reference as if fully set forth herein.

### BACKGROUND

Light emitting diodes (LEDs) are becoming increasingly common as light sources. They are highly energy efficient and may have operating of lifetimes well in excess 50,000 hours. White LEDs can be produced by a number of different methods. Some of these include combinations of monochromatic LEDs. This requires at least two different monochromatic LEDs (i.e. blue and amber), but may commonly include three different monochromatic LEDs (i.e. red, green and blue) and may include four (blue, green, amber, red) or more different monochromatic LEDs if a high CRI is desired.

Use of multiple monochromatic LEDs requires use of a multi-channel electrical driver as the output of each color of LED needs to be set independently to give a desired chromaticity. Thus a tri-chromatic white LED system (i.e. red, green and blue LEDs) requires setting three different LED currents. This greatly increases complexity of a light and production cost.

A common alternative to use of multiple monochromatic LEDs to produce white light is phosphor conversion. Phosphor converted LEDs commonly use a blue LED with a broad band Stokes phosphor material to produce white light. This simplified production since only a type of LED is required and a single electrical driver may be used to power the LEDs with lowers cost.

Unfortunately phosphor converted LEDs are generally limits to CRI values of about 85. Higher CRI values can be achieved, but only at the expense of reduced efficiency. Phosphor converted white LEDs are usually deficient in red light. Use of a broad emission band phosphor means that adding significant amounts of red light to the emission spectrum also adds significant amounts of deep red light which the human eye is not able to perceive efficiently.

An alternative means of producing white light with a high CRI value is exemplified in so called hybrid white LED systems. These systems commonly use two different LED types. One is a blue LED with a broad emission band phosphor and the other a monochromatic red or orange LED.

These types of LEDs are commonly acknowledge to be capable of high CRI values (i.e. about 90 to about 95) with high efficiency. This requires a dual driver system to provide current to the LEDs.

In order to produce light with a consistent chromaticity temperature feedback is required in order to adjust the current through each type of LED in a hybrid white LED system. This feature can be ignored to reduce cost, but as will be shown later this can result in dramatic shifts in perceived color.

All LEDs exhibit changes in spectral output as a function of drive current and operating temperature. The differences as a function of drive current are less significant than those due to changes in operating temperature. They are acknowledged to exist, but are not discussed in detail herein.

There are two significant changes in LED spectral output as a function of temperature: peak wavelength shift and efficiency. Generally LED emission wavelength increases with operating temperature. More significantly LED efficiency (light output) decreases with increasing operating temperature.

For monochromatic blue and green LEDs based on gallium nitride materials, the change in efficiency is partially compensated for by the change in wavelength. The human eye is most sensitive to light with a wavelength of about 555 nm. Blue and green LEDs have peak emission wavelengths of about 450-470 nm and about 505-540 nm respectively. Shifts towards longer wavelengths shift emission towards the maximum of eye sensitivity to changes in total output are compensated for.

For longer wavelength LEDs (i.e. yellow, amber, orange, red) the change in peak emission wavelength is exaggerates the decrease in light output. These LEDs are commonly based on aluminum indium gallium phosphide (AlInGaP) materials. As the temperature of an AlInGaP LED increases its peak emission wavelength shifts away from the maximum of the eye sensitivity. Thus even if the total optical power from an AlInGaP LED remained constant as its operating temperature increased, its perceived brightness would decrease.

The fact that the peak emission wavelength of AlInGaP LEDs shifts to longer wavelength as the operating efficiency decreases exaggerates the changes and such LEDs are noticed to have significant changes in brightness with operating temperature.

Changes or differences in chromaticity may be expressed using a metric known as Standard Deviation of Color Measurement (SDCM). It is desirable for light sources to exhibit SDCM changes of about 3 or less during warm up. Unfortunately the warm white LEDs described previously exhibit chromaticity changes greater than SDCM 10.

In order to combat this performance issue independent drivers are used for the GaN based and AlInGaP based LEDs used in these devices. This allows the relative current through each type of LED to be adjusted to maintain approximately constant chromaticity. This approach also requires incorporation of some type of temperature sensor in order to make the appropriate adjustments.

The use of two independent drivers, a temperature sensor and a microprocessor to calculate the changes in operating current required to maintain approximately constant chromaticity greatly add to the complexity, size and production cost of warm white hybrid LED lights.

Thermochromic materials change optical properties with temperature. The most typical changes are related to the reflective and absorptive properties. Examples of these materials include liquid crystal based materials and leuco dye based materials. Liquid crystal based materials can exhibit a wide range of color changes that cover the entire gamut of colors from violet to blue to green to yellow to orange to red. In contrast leuco dye materials typically change from a colored state at a low temperature to a transparent state at a high temperature. These color changes are reversible and repeatable. The temperature at which the chromatic properties begin to change and the temperature at which the chromatic properties complete the change can be designed and adjusted. The temperature at which the chromatic properties begin to change is commonly known as the transition temperature.

Leuco dye materials may be applied over a colored surface to result in a surface that changes from one color to another color instead of going from a colored state to a transparent state. Similarly multiple layers of leuco dye materials may be applied to provide a larger gamut of color changes, each of which happen at a pre-determined temperature. This type of thermochromic optic posses a reflection spectrum that changes with respect to temperature. Thermochromic liquid crystals may be applied to surfaces to produce similar classes of optics.

Leuco dye materials may also be incorporated into a transparent or translucent polymeric material. When used in this manner leuco dye materials produce an optic with a transmission spectrum that changes with respect to temperature.

These materials may be incorporated into transparent materials to form a refractive or translucent optic whose transmission spectrum changes with temperature. They may also be coated onto a reflective material to produce a reflective optical element whose reflection spectrum changes with temperature.

In some cases a means of temperature control may also be provided adjacent a thermochromic optic to affect changes to the chromaticity of the light unit without changing the driver current to the light sources.

### DEFINITIONS

Chromaticity: The term “chromaticity” is used herein to refer to an objective quality of color regardless of its luminance. Chromaticity is a two parameter representation of color. Two different chromaticity systems are used herein: 1931 x-y chromaticity and 1976 u′-v′ chromaticity. The 1931 x-y chromaticity system is most commonly used in the industry due to historical reasons. Despite this it is noted that the 1931 x-y chromaticity system is highly non-uniform. This means that a perceived difference in two chromaticity does not correlate well with the distance between their chromaticity coordinates. The 1976 u′-v′ chromaticity system is on the same fundamental research, but has been modified to result in a more uniform chromaticity space so that the perceived difference in colors correlates well with the distance between chromaticity coordinates.

CCT: The term “CCT” is used herein to refer to correlated color temperature. CCT is defined using the CIE 1960 u-v chromaticity diagram as the color temperature of the closest point on the black body locus to the chromaticity coordinates of the light source being described. CCT has values of ° K and is commonly considered a measure of the shade of white light.

CRI: The term “CRI” is used herein to refer to general Color Rendering Index as defined by CIE 13.3.

Hybrid white LED: The term “hybrid white LED” is used herein to refer to a lighting system that incorporates a long wavelength (i.e. amber, orange or red) and a phosphor converted LED that uses an LED with a peak emission wavelength between about 380 nm and about 470 nm to stimulate emission from a phosphor material.

Leuco dye: The term “leuco dye” is used herein to refer to a dye whose molecular structure alternates between two different states at different temperatures. Typically one structure is transparent and the other structure has a notable color.

Just Noticeable Color Difference: The term “just noticeable color difference” is defined herein as SDCM=3. Chromaticity coordinates with SDCM<3 will generally be considered to have the same perceived color. Chromaticity coordinates with SDCM>3 will generally be considered to have a noticeable color difference. The greater the values of SDCM above 3 the more obvious to observed color difference.

Light Emitting Diode, LED: The terms “light emitting diode” and LED are used herein in their broadest term of meanings and encompass and semiconductor based device that includes a p-n junction and when forward biased emits light by recombination of electrons and holes. This includes semiconductor p-n junctions comprising inorganic and organic materials. The terms also include devices that incorporate optical resonance phenomenon and stimulated emission.

SDCM: The term “SDCM” is used herein to refer to the concept of Standard Deviation of Color Measurement. It is defined herein as the mathematical distant between two chromaticity coordinates in 1976 u′-v′ chromaticity diagram multiplied by 1,000.

Thermochromic: The term “thermochromic” is used herein to refer to a material whose reflectance spectrum with respect to at least one wavelength range changes with temperature. The term “thermochromic” is also used herein to refer to a material whose transmission spectrum at least one wavelength range changes with respect to temperature. Thermochromic materials are commonly incorporate leuco dyes or liquid crystal materials.

### BRIEF SUMMARY OF THE INVENTION

The present invention comprises an optical element whose reflective or transmissive spectral properties change with respect to temperature. Although nominally intended for use in hybrid white LED lighting systems it is acknowledged that the present invention has applications in other types of lighting systems.

In one embodiment a light fixture includes a light source whose chromaticity changes with temperature. The light fixture also includes at least one thermochromic optical element that receives at least a portion of the light emitted by the light source. The thermochromic optical element is disposed in a manner such that it redirects the received light so that the redirected light exits the light fixture. The light source whose chromaticity changes with respect to temperature is further mounted to a heat sink or other heat dissipating structure. At least one thermal transfer member connects the heat sink and at least one support structure for the thermochromic optical. The support structure is designed to transfer heat conducted from the heat sink and thermal transfer member to the thermochromic optic.

In this manner heat is conducted from the light source to the thermochromic optic. As a result of this design the temperatures of the light source and the thermochromic optic will be correlated. It is not necessary for the temperatures of the light source and the thermochromic optical element to be the same or even to be tightly correlated. As long as the trend between the two temperatures can be established it is possible to design a thermochromic optic that is able to minimize changes in the chromaticity of light emitted by the light fixture.

In another embodiment a light fixture includes a light source whose chromaticity changes with respect to temperature is connected to a heat sink or other heat dissipating structure. The light source further comprised a thermochromic optical element disposed to receive at least a portion of the light emitted by the light source. The thermochromic optical element is disposed in a manner such that it redirects the received light so that the redirected light exits the light fixture. The thermochromic optic is mounted remotely from the heat sink. A fan or other air moving device directs air across the heat sink and towards the thermochromic optical element. In this manner heat from the light source is transferred to the thermochromic optical element.

In this manner the correlation between the light source temperature and the thermochromic optical element is effected by means of convective heat transfer. This correlation between operating temperatures enables the thermochromic optical element to compensate for changes in the chromaticity of the light source.

In another embodiment a light fixture includes a light source whose chromaticity changes with temperature. The light source is in thermal contact with a heat sink or other thermal dissipating structure. A thermochromic optical element is disposed to receive at least a portion of the light emitted by the light source and is thermally isolated from the light source. The thermochromic optical element is disposed in a manner such that it redirects the received light so that the redirected light exits the light fixture.

The heat sink on which the light source is mounted further comprises a means for monitoring temperature. Information on heat sink temperature is transferred to a control device. The control device is further in communication with an electrical temperature control device in thermal contact with the thermochromic optical element. The temperature control device is thus able to adjust the temperature of the thermochromic optical element in a manner that minimizes changes in the chromaticity of light emitted by the light fixture despite changes in chromaticity of the light source as a function of temperature.

In another embodiment an LED package includes at least one thermochromic optical element disposed to receive at least a portion of the light emitted by at least one LED chip. The thermochromic optical element is disposed in a manner such that it redirects the received light so that the redirected light exits the LED package. The thermochromic optical element is further disposed so as to have a thermal connection to the LED. In this manner the thermochromic optical element is able to compensate for changes in the optical emission of the LED. In this manner an LED package may be produced with reduced changes in optical output as a function of its operating temperature.

Inside an LED package, the thermochromic element may take several forms. It may be a cap layer on top of the encapsulation, a reflective material on the walls of the cup or may be present the encapsulation material itself.

In this embodiment the thermochromic material may comprise a silicone or epoxy resin with a thermochromic dye or pigment dispersed within the body of the resin. It may further include a phosphorescent material.

### BRIEF DESCRIPTION OF THE DRAWINGS

FIG. 1. illustrates shows the change in luminous flux versus temperature for various type of LEDs. The luminous flux is normalized to 100% at 25° C. The behavior of white LEDs is very similar to the behavior of blue LEDs.

FIG. 2 is a partially exploded view of an light emitting fixture incorporating an optical element of the present invention.

FIG. 3A, 3B shows typical spectral power distributions for a hybrid white LED system at room temperature and at stable operating temperature.

FIG. 3B shows a partial view of the 1931 CIE chromaticity diagram showing the chromaticity coordinates of the spectral power distributions of FIG. 3A.

FIG. 4 shows the transmission spectrum of an optical element of the present invention at room temperature and at operating temperature.

FIG. 5A shows the spectral power distribution of a hybrid white LED system after passing through an optical element of the present invention at room temperature and at operating temperature.

FIG. 5B shows a partial view of the 1931 CIE chromaticity diagram showing the chromaticity coordinates of the spectral power distributions of FIG. 5A.

FIG. 6 shows a partial cut away view of an LED package according to the present invention.

### DETAILED DESCRIPTION OF THE DRAWINGS

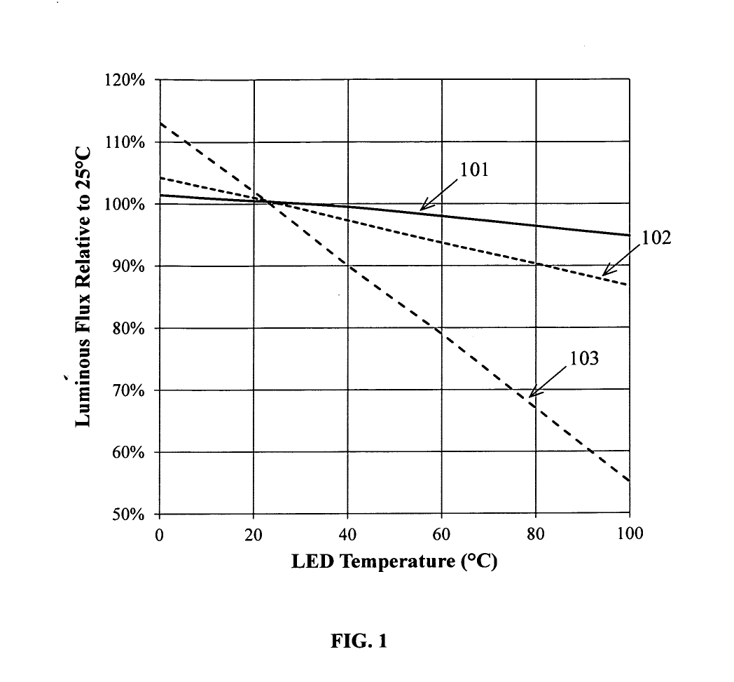

FIG. 1 illustrates the typical luminous flux behavior of various LEDs as a function of their operating temperature. Blue LEDs 101 show the least decrease in luminous output as a function of operating temperature. Common phosphor converted LEDs utilize a blue LED to excite one or more phosphors and have a luminous flux behavior with respect to operating temperature that closely matches that of blue LEDs 101.

Green LEDs 102 show a slightly greater decrease in luminous flux with respect to operating temperature. This is in part due to the fact that the peak emission wavelength of green LEDs is closer to the wavelength of maximum eye sensitivity. In this region the change in eye sensitivity with respect to wavelength is less pronounced and the phenomenon is does not compensate for decreased optical radiance as well as for blue LEDs.

As previously noted AlInGaP LEDs show a very pronounced decrease in luminous flux with respect to operating temperature. Red LEDs 103 may show decreases in luminous flux of over 40% between operation at 25° C. and 100° C.

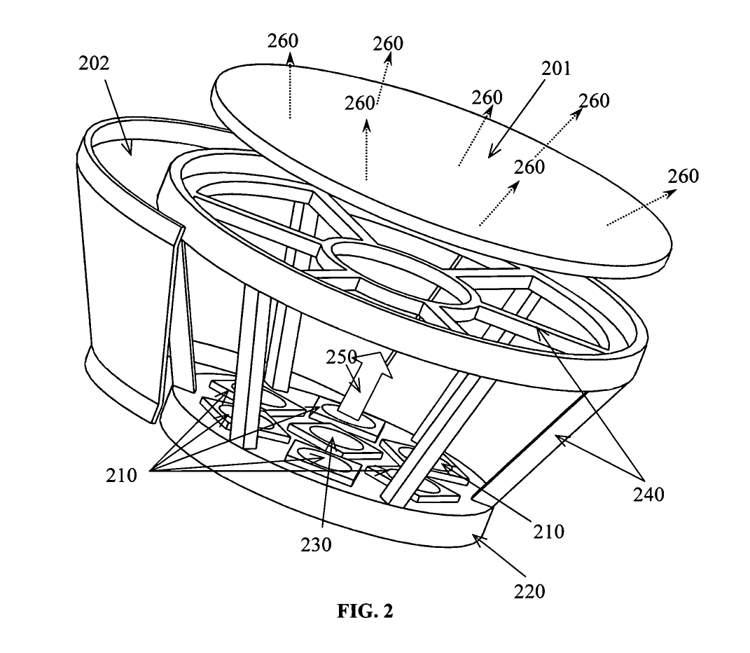

FIG. 2 shows a partially exploded view of one embodiment of the present invention. Phosphor converted LEDs 210 and a red LED 230 are mounted to a heat sink 220. Thermal transfer members 240 extend from the heat sink and make thermal contact to a refractive thermochromic optic 201. The spectral power distribution of the collective light 250 emitted by the phosphor converted LEDs 210 and the red LED 230 is modified by the refractive thermochromic optic 201 to produce emitted light 260 with a different spectral power distribution and chromaticity.

In some embodiments a reflective thermochromic optical element 202 may be used in place of the reflective thermochromic optical element 201. In some embodiments a reflective thermochromic element 202 and a refractive thermochromic optical element 203 may used. In these embodiments there it spectral modifications made by each thermochromic optical element 201, 202 may be different. In some embodiments multiple thermochromic optical elements 201, 202 may be used. In these embodiments each thermochromic optical element may perform a different spectral modification or the same spectral modification.

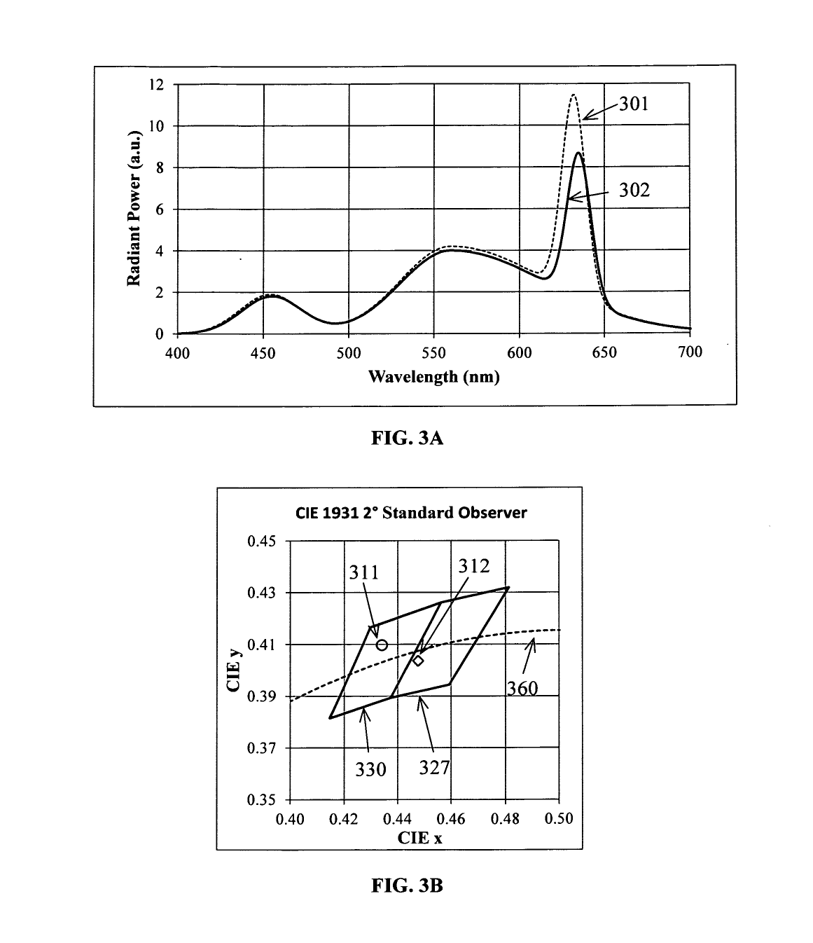

FIG. 3A shows the spectral power distribution (SPD) for a typical hybrid white LED fixture represented in FIG. 1. Significant differences are noted between the cold spectral power distribution 301 and the hot spectral power distribution 302. A significant difference in the intensity of the emission peak from the red LED 130 around 630-635 nm is particularly noteworthy.

The changes in chromaticity of the cold spectral power distribution 301 and the hot spectral power distribution 302 are quantified in FIG. 3B. FIG. 3B shows a portion of the 1931 CIE x-y chromaticity diagram. The so called black body locus 360 is indicated by the dashed line. This is the locus of chromaticity coordinates for nominally ideal white light.

Industry standard chromaticity ranges for white LEDs have been established in ANSI/NEMA C78.377-2008. This document establishing nominally accepted chromaticity bins or allowable variations in chromaticity for various target CCT values of white LED products. Notably the chromaticity bins defined in this document exceed a just noticeably color difference. The variation in the direction parallel to the black body locus is approximately SDCM=7. The ANSI chromaticity bins for 2700° K 327 and 3000° K 330 are shown for reference.

Chromaticity coordinates corresponding to the cold spectral power distribution 312 and the hot spectral power distribution 311 are shown.

Numerical chromaticity information from FIG. 3B are shown in Table 1 below. The CCT value of the hybrid white light source is noted to increase by about 271° K and the difference in chromaticity corresponds to SDCM=11.3. As noted previously it is generally desirable for changes in chromaticity of a light source during warm up to be less than about SDCM=3.

TABLE 1
Hybrid White LED

| | CIE x | CIE y | CCT | CIE u′ | CIE v′ |
|---|---|---|---|---|---|
| Cold SPD | 0.4476 | 0.4036 | 2,824° K | 0.2577 | 0.5228 |
| Hot SPD | 0.4341 | 0.4097 | 3,095° K | 0.2464 | 0.5232 |

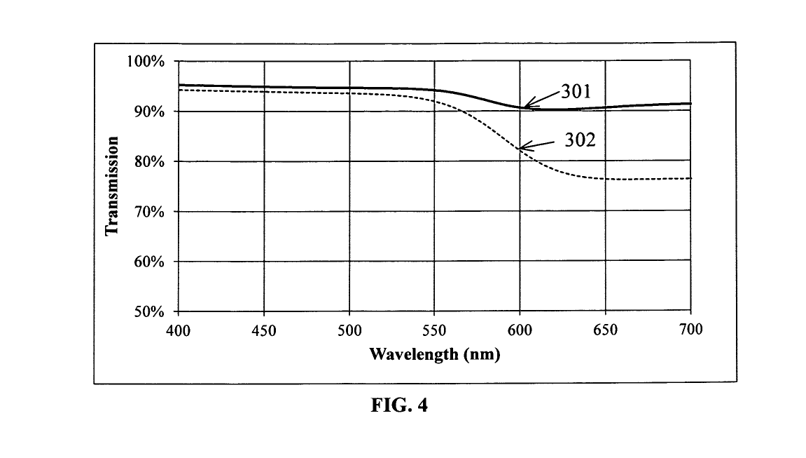

FIG. 4 shows the transmission spectrum for the refractive thermochromic optical element of FIG. 2. The transmission spectrum for the hot operating temperature 301 is shown as well as the transmission spectrum for the cold operating temperature 302. In this embodiment the refractive thermochromic optical element 201 comprises a transparent polymeric material with a thermochromic pigment that has a green body color in at low temperatures as evidenced by a pronounced absorption in the red regions of the spectrum at low operating temperatures. In this manner the refractive thermochromic optical element 201 absorbs a portion of the red light. As the red LED 230 temperature increases the output of red light will begin to decrease. Simultaneously the temperature of the refractive thermochromic optic 201 begins to increase and the transmission in the red portion of the spectrum increases.

In this manner the coupling of the operating temperature of the LED light sources 210, 230 to the refractive thermochromic optical element operate in a manner that minimizes changes in chromaticity of the light output of the fixture.

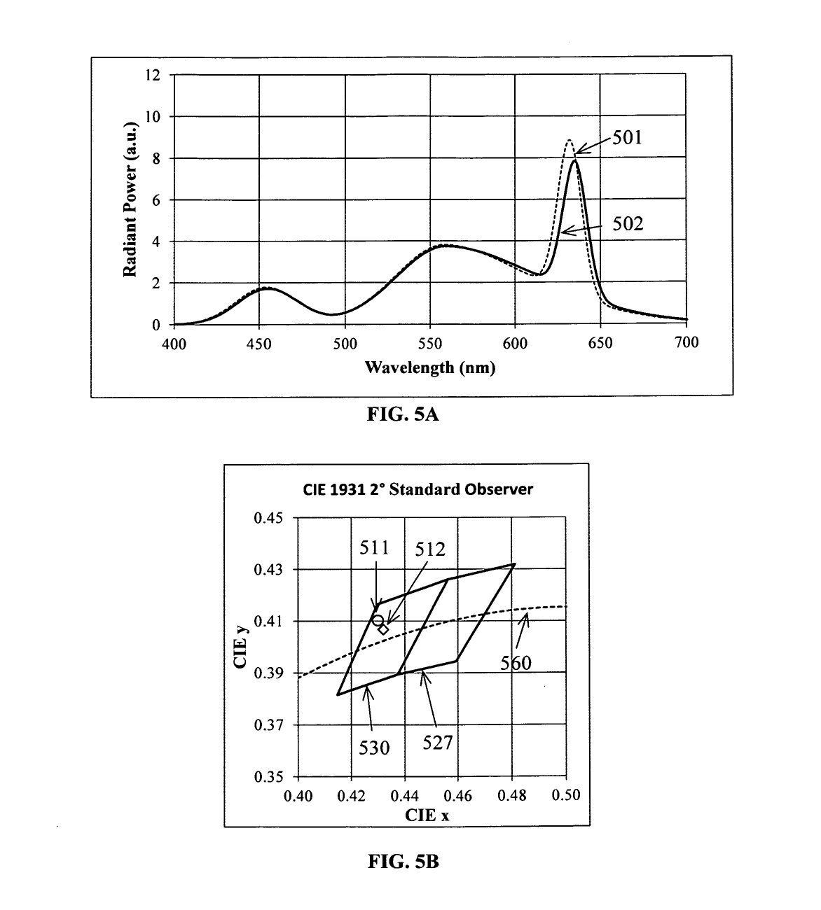

These changes are more evident when the spectral power distribution of the fixture is compared at cold temperatures and at high temperatures as shown in FIG. 5A. It is noted that there is still a difference in the intensity and position of the emission from the red LED 230. However, the differences between the cold fixture SPD 501 and the hot fixture SPD 502 are much smaller. This is evidenced in FIG. 5B which shows the corresponding chromaticity coordinates.

As before the chromaticity coordinates are shown using the 1931 CIE x-y chromaticity system. The black body locus 560 is shown along with the ASNI/NEMA C.78.377-2008 chromaticity bins for 2700° K 527 and 3000° K 530. In this instance the chromaticity coordinates of the fixture at cold temperature conditions 512 is noted to be near the center of the ANSI 3000° K chromaticity bin 530. The chromaticity coordinates of the fixture at hot operating conditions 511 are noted to be slightly above and to the left of the chromaticity coordinates of the fixture under cold operating conditions 512.

These differences are detailed in Table 2 below. A noticeable reduction in shift of CCT value is noted: about 63° K when the refractive thermochromic optical element 201 is used compared to about 271° K without use of the thermochromic optical element 201. Most notable the chromaticity shift between cold operating temperature and hot operating temperature has decreased from about SDCM=11.3 to about SDCM=2.9.

TABLE 2
Hybrid White LED with Thermochromic Optical Element

| | CIE x | CIE y | CCT | CIE u′ | CIE v′ |
|---|---|---|---|---|---|
| Cold SPD | 0.4319 | 0.4067 | 3,108° K | 0.2462 | 0.5217 |
| Hot SPD | 0.4299 | 0.4102 | 3,171° K | 0.2435 | 0.5227 |

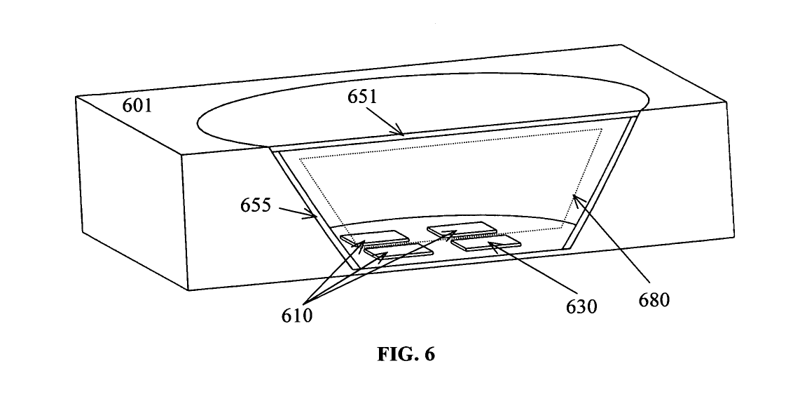

FIG. 6 shows a partial cutaway view of another embodiment of the present invention. A red LED chip 630 is mounted inside and LED package 601. Blue LED chips 610 are also mounted in the LED package 601. A reflective thermochromic optical element 655 may be incorporated into the walls of LED package cup. Alternatively a refractive thermochromic optical element 651 may be disposed over the cup fill encapsulant 680. The cup fill encapsulant 680 comprises an epoxy or silicone resin material and at least one phosphor material. Light from the blue LED chips 610 interacts with the phosphor material and is converted to nominally white light.

The light from the red LED chip 630 is scattered by the phosphor material but is not significantly absorbed by the phosphor material or the resin. Interactions between the light emitted by the red LED 630 and the reflective thermochromic optical element 651 and or the reflective thermochromic optical element 655 minimize changes in the chromaticity of light emitted by the LED package.

This in turn allows all the LEDs to be connected in a single series configuration so that the LED may be operated using a single channel power supply.

While the invention has been described in detail in connection with only a limited number of embodiments, it should be readily understood that the invention is not limited to such disclosed embodiments, rather, the invention can be modified to incorporate any variations, alterations, substitutions or equivalent arrangements not heretofore described, but are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed:

1. A refractive thermochromic optical element comprising
a transparent or translucent polymeric material
a thermochromic material wherein said thermochromic material effects a reversible change in the transmission spectrum of said refractive thermochromic optical element as the temperature of said refractive thermochromic optical element

2. A reflective thermochromic optical element comprising
a reflective material wherein said reflective materials properties are diffuse, specular or a combination of diffuse and specular
a thermochromic material wherein said thermochromic material effects a reversible change in the reflectance spectrum of said reflective thermochromic optical element as the temperature of said reflective thermochromic optical element

3. An LED package comprising
at least a first LED device with a peak emission wavelength between about 380 nm and about 480 nm
at least a second LED device with a peak emission wavelength between about 580 nm and about 650 nm
a thermochromic optical element
an encapsulating material that encapsulates said first LED device and said second LED device

4. An LED package of claim 3 wherein said encapsulating material comprises a phosphor material
